(19) United States
(12) Patent Application Publication
(10) Pub. No.: US 2025/0110179 A1
(43) Pub. Date: Apr. 3, 2025

(54) Method for the Model-Based Estimation of the Impedance of a Galvanic Cell of a Secondary Battery and Its Use, as Well as a Battery Cell Monitoring Device and Vehicle

(71) Applicant: Mercedes-Benz Group AG, Stuttgart (DE)

(72) Inventors: Yassine BENSAAD, Stuttgart (DE); Fabian FRIEDRICHS, Stuttgart (DE); Thorsten BAUMHOEFER, Illingen (DE); Judith BAEHR, Nuertingen (DE)

(21) Appl. No.: 18/832,870

(22) PCT Filed: Nov. 9, 2023
(86) PCT No.: PCT/EP2023/081302

§ 371 Date: Jul. 24, 2024

(30) Foreign Application Priority Data
Dec. 19, 2022 (DE) 10 2022 004 803.5

(51) Int. Cl. G01R 31/367; B60L 58/16; G01R 19/165; G01R 31/36; G01R 31/3842; G01R 31/389; G01R 31/392; G01R 31/396

(52) U.S. Cl. CPC G01R 31/367; B60L 58/16; G01R 19/16528; G01R 31/3648; G01R 31/3842; G01R 31/389; G01R 31/392; G01R 31/396

(57) ABSTRACT

A method for the model-based estimation of the impedance of a galvanic cell of a secondary battery by an estimation model run on a computing unit. The method includes the following method steps carried out prior to the actual use of the galvanic cell: initially parameterizing the cell model; generating a reference database; fitting a respective model parameter reference value from the reference database by polynomial fitting and saving the fitting coefficients determined in the process in a data memory. The method includes the following method steps carried out during the actual use of the galvanic cell: determining the difference from a measured cell voltage and a cell voltage calculated by the cell model; specifying a gain factor and multiplying the voltage difference by the gain factor; and incrementally determining the impedance of the galvanic cell.

### BACKGROUND AND SUMMARY OF THE INVENTION

The invention relates to a method for the model-based estimation of the impedance of a galvanic cell of a secondary battery by means of an estimation model running on a computing unit according to the type defined in more detail herein, to a battery cell monitoring device according to the type defined herein, to the use of the method for determining the service life of battery cells of a traction battery of a vehicle according to the type defined in more detail herein, as well as to a vehicle according to the type defined in more detail herein.

Owing their high energy and power density, lithium-ion batteries are essential for the development and in the operation of electromobility concepts in electric vehicles. A battery management system (BMS) controls the battery packs used in mobile applications and ensures their optimum performance.

An exact estimation of the health status, also referred to as state of health (SOH), is crucial for the operational safety of electric vehicles. The increase of the internal resistance, also referred to as the state of heath resistance (SOHR), in the course of ageing is considered one of the most important degradation phenomena which restrict the performance and service life of battery cells. Furthermore, the internal resistance is essential for the thermal analysis of the cell and temperature monitoring. The internal resistance of a cell depends greatly on the temperature and the charging state, also referred to as state of charge (SOC).

The accurate prediction of the cell internal resistance prevents unnecessarily large failure reserves in the battery design and use and thus enables the actual performance and service life limits to be exploited in real operation. Premature and unnecessary battery replacement is consequently prevented and thus significantly increases the level of sustainability of electric vehicles.

The impedance, i.e., the alternating current resistance of battery cells, can be measured with the aid of electrochemical impedance spectroscopy. However, this is comparatively expensive and time-consuming due to the measurement technology required and the effort involved. The measurement of the impedance of battery cells in the vehicle is thus impractical.

Instead, the impedance curve of the battery cells of a traction battery of a vehicle is estimated with the aid of computational models during running operation. The basis of such a calculation model is an electrical equivalent model of the battery, which in turn is based on an electronic equivalent circuit diagram. The components contained in such an equivalent circuit diagram, such as resistors, coils, capacitors and the like, are equally subject to ageing effects, which have an impact on the impedance. In order to be able to calculate a realistic impedance, it is therefore necessary to correctly estimate the parameters of these electronic components over their service life, taking ageing into account.

DE 10 2019 127 384 A1 discloses a method for parameter estimation in an impedance model of a lithium-ion cell. The parameters found by means of measurement are implemented in a computing unit of a vehicle for use by a computational model for determining the impedance. The measurements are thus carried out in the vehicle.

An extensive overview about common methods for battery parameter estimation is also known from Y: C. Fleischer, W. Waag, H.-M. Heyn, and D. U. Sauer. On-line adaptive battery impedance parameter and state estimation considering physical principles in reduced order equivalent circuit diagram battery models: Part 1. requirements, critical review of methods and modelling. Journal of Power Sources, 260:276-291, 2014. The authors propose a self-developed estimation model which is described together with the calculation results and an evaluation of the prediction accuracy in a second paper. See in this regard, Y: C. Fleischer, W. Waag, H.-M. Heyn, and D. U. Sauer. On-line adaptive battery impedance parameter and state estimation considering physical principles in reduced order equivalent circuit diagram battery models part 2. parameter and state estimation. Journal of Power Sources, 262:457-482, 2014.

To find relevant model parameters, a computationally complex closed-form optimization problem is solved online in the vehicle during operation thereof. A recursive estimator based on the method of least squares is used for this purpose. This is only possible due to the linearity of the simplified calculation model, as the computing resources in the vehicle are limited, solving an optimization problem is computationally intensive and time-consuming and therefore a solution cannot otherwise be obtained in the vehicle in a reasonable time. The temperature dependency of the model parameters is also estimated on-board. Estimating the temperature dependency makes prediction quality worse. In addition, a computationally complex iterative mutation algorithm is used to estimate the current dependency.

The present invention is based on the object of providing an improved method for the model-based estimation of the impedance of a galvanic cell of a secondary battery, which is suitable for use in vehicles during their operation and has an increased prediction quality.

A generic method for model-based estimation of the impedance of a galvanic cell of a secondary battery by means of an estimation model run on a computing unit, wherein at least some of the model parameters of an equivalent circuit diagram of the cell are adapted in a cell model contained in the estimation model over the service life of the cell, wherein the equivalent circuit diagram comprises at least one resistance element and one capacitance element, is developed according to the invention in that the following method steps are carried out prior to the actual use of the cell:
initially parameterizing the cell model based on measurement series of electrochemical impedance spectroscopy of a structurally identical cell;
generating a reference database, comprising an allocation of model parameter reference values and corresponding impedance reference values over a service life characteristic diagram of the structurally identical cell, by:
   impressing a plurality of temperature-specific charging and discharging profiles, each comprising a voltage curve of the cell over time, on the estimation model;
   adjusting the model parameters to be adapted of the equivalent circuit diagram by means of a non-linear optimizer, wherein a difference between measured cell voltage and cell voltage calculated by the cell model is formed and minimized, wherein model parameters found in respective minima are used to form the model parameter reference values; and
   calculating the impedance reference values corresponding to the model parameter reference values;
fitting a respective model parameter reference value from the reference database by means of polynomial fitting and saving the determined fitting coefficients determined in the process in a data memory; and the following method steps are carried out during the actual use of the cell:
determining the difference from a measured cell voltage and a cell voltage calculated by means of the cell model;
specifying a gain factor and multiplying the voltage difference, determined in the previous method step, by the gain factor; and
incrementally determining the impedance of the cell, wherein the next increment of the impedance is calculated by adding the current increment of the impedance to the product calculated in the previous method step of gain factor and voltage difference, wherein subsequently the variable model parameters are adjusted to the next increment of the impedance thus calculated, taking the fitting coefficients into account.

The method according to the invention enables a particularly exact and thus reliable estimation of the impedance of battery cells and thus has a comparably low computing requirement. The method is suitable particularly for use in the running operation of a vehicle. This means that no optimization has to be carried out in the vehicle itself in order to determine the appropriate model parameters for the respective operating state of the battery. Instead, these model parameters are initially estimated in a laboratory or a test vehicle, i.e., off-board of a production vehicle, and are determined with the aid of fitting for all possible states. These reference values are then used for the respective actual use case in the (production) vehicle. The voltage difference between measured and estimated terminal voltage considered for calculating the impedance is thus evaluated for each sampling period, which allows a particularly high-resolution analysis over time.

The method according to the invention provides for collecting information about the changes in the electrical cell behavior over the service life of the cell offline or off-board, i.e., not during operation of the vehicle itself, but for example in a laboratory or test vehicle. This cell behavior is typical of cells of a particular construction type and can therefore be transferred to structurally identical cells. The method steps carried out prior to the actual use of the cell can therefore be carried out on any structurally identical cell in a laboratory and the method steps carried out during the actual use of the cell can be carried out on a secondary battery that differs therefrom with corresponding structurally identical cells. This secondary battery can be used as a voltage source in any machine, such as a vehicle, in order to operate it.

The construction of an equivalent circuit diagram of a cell and its implementation in a computing unit are common practice. However, the question arises as to how ageing-dependent model parameters can be adapted to their physically correct values over the service life of the secondary battery. For the cell type under consideration, to this end, a complete parameterization of the estimation model or the equivalent circuit diagram and thus of the electrical part of the cell model is carried out based on electrochemical impedance spectroscopy measurements (EIS measurements) of a brand-new cell, whereby the physical behavior of this “beginning-of-life” (BOL) cell is reproduced in a comparatively physically correct manner. The physical behavior of the cell is dependent on the temperature and the state of charge. The EIS measurements involve carrying out various series of measurements at different states of charge between 0 and 100% and temperatures between −20° C. and +45° C., for example. Temperature dependencies are fitted on the basis of Arrhenius functions. Arrhenius functions describe the behavior between reaction kinetics in the battery cell to respective temperatures. The Arrhenius functions found in this way are saved and permanently integrated into the estimation model for later use. The dependencies on different states of charge are stored in the estimation model in the form of factors from look-up tables. In addition to the temperature dependency, the dependency on different states of charge (SOC) therefore also remains constant over the service life of the galvanic cell.

The EIS measurements can be carried out on one or more individual cells or on various cells combined to form a battery module.

The next step is to adapt the “start” parameterization found for this brand-new cell or cells (BOL cells) over its service life. The estimation model is introduced into a battery cell monitoring device in order to find the course of all relevant model parameters that assume changed values as the cell ages. Such a battery cell monitoring device comprises detecting means for detecting the current that can be output from at least one cell of the secondary battery, the terminal voltage and the battery temperature at any point, in particular the cell temperature of the monitored cell. The battery cell monitoring device further comprises a data memory and a computing unit on which the estimation model is implemented. Then an already aged secondary battery comprising a large number of structurally identical cells is used, and emulated, simulated or real discharging and charging profiles are impressed on this secondary battery.

Such discharging and charging profiles can be generated, for example, with test drives with a vehicle. For example, discharging takes place while the vehicle is travelling for relatively a long period of time, such as two hours. The vehicle can also operate a corresponding electric motor in generator mode and thus feed electrical energy into the secondary battery to charge the battery cells due to recuperation. Such charging processes take a comparatively short time, in the order of several seconds. A charging profile is, for example, a charging process actually carried out at a charging station. For example, the secondary battery is charged from a state of charge of 20% to a state of charge of 85% within several minutes, for example 40 minutes. The discharging and charging profiles can be impressed in the vehicle itself or on a dismantled traction battery installed on a test bench. The actual, simulated or emulated discharging and charging profiles are then impressed on this test bench.

Each cell of the secondary battery exhibits a different ageing condition over the course of its service life. Accordingly, the individual battery cells of the traction battery under consideration have a different impedance. The reference database is then created using the estimation model and the measured variables. The model parameters, which vary over the service life and corresponding ageing, are determined using a non-linear optimizer. For this purpose, the estimation model compares the measured and estimated voltage values and minimizes them until the deviation is minimal, ideally zero. Model parameters found in the respective minima are then used to form the model parameter reference values. These are specific values (corresponding to the series of measurements carried out). In later vehicle operation, however, the cells will typically assume any impedance values, which are not necessarily included in these measurement series. In order to nevertheless include model parameters for these impedance values in the reference database, fitting functions are determined for each model parameter that correspond to a curve of the variable model parameter over the impedance. For this purpose, common polynomial fitting methods are used. Polynomials of the nth order can be used. However, the use of second-order polynomials, i.e., quadratic functions, has proven to be particularly advantageous in this case, as this represents a good ratio of accuracy to computational effort.

Thus, there is a knowledge base as to which characteristics a respective ageing-specific model parameter assumes over a respective impedance value. This is a core idea of the invention, as it means that the computationally intensive optimization has to be outsourced from the vehicles to the laboratory or a test vehicle and only needs to be carried out once for each different cell type.

The fitting coefficients calculated in the process are saved in a data memory. The data memory is a part of the computing device or of a test bench. The fitting coefficients can be distributed from the data memory to any number of other computing units and implemented there. For example, this is the battery management system of a vehicle's traction battery.

The estimation model can then be used in the running operation of a vehicle for estimating the impedance of the battery cells of the traction battery of the vehicle. This enables estimation of the impedance of the cells of the traction battery of the vehicle during its operation. For this purpose, the estimation model is implemented in the computing unit of a vehicle, for example in a separate computing unit, the BMS or a battery cell monitoring device or similar.

An advantageous development of the method according to the invention provides that the equivalent circuit diagram of the cell additionally contains at least one of the following further elements:
a ZARC element (ZARC);
a coil element;
a finite length Warburg element; and/or
a finite space Warburg element.

By adding these elements to the equivalent circuit diagram of the cell, a particularly realistic equivalent circuit diagram and thus an electrical cell model can be generated. This provides the best possible mathematical description of the physical processes of the individual cells. A single resistance represents the electrical resistance of conductive material, such as the arresters on the electrodes, cables within the battery and the limited conductivity of the electrolyte.

A coil can be included to represent inductive behavior in the equivalent circuit diagram. Inductive behavior occurs due to metallic contacts inside the cell.

A ZARC element consists of an ohmic resistor which is connected in parallel to a capacitor. A ZARC element models the effect of double layers and charge transfer. This enables non-linear voltage dependencies to be taken into account. ZARC elements can be used to describe the high-frequency part of the cell impedances.

The low-frequency part of the cell impedances can be described with the aid of Warburg elements. Warburg elements detect processes which describe the comparatively slow ion diffusion inside the electrodes. A finite space Warburg element represents a non-conductive boundary layer in the case of a maximum diffusion length, whereas a finite length Warburg element describes a perfect conductive boundary layer in the case of maximum diffusion length.

According to a further advantageous embodiment of the method, the voltage difference of the measured cell voltage and the calculated cell voltage is low-pass-filtered prior to multiplication by the gain factor. This stabilizes the parameter adjustment of the model parameters and makes it possible to distinguish short-term model faults from parameter learning errors as far as possible.

A further advantageous embodiment of the method provides that the cell model for calculating the cell voltage takes into account a term for the excess voltage, the hysteresis voltage and the open-circuit voltage, respectively. The open-circuit voltage is approximated by the weighted average of the low-pas-filtered difference of the terminal and excess voltage and the open-circuit voltage calculated by current integration. The hysteresis voltage is provided by a parallel software module according to the modified Plett model for example, presented by D. Wycisk, M. Oldenburger, M. G. Stoye, T. Mrkonjic, and A. Latz. Modified plett-model for modelling voltage hysteresis in lithium-ion cells. Journal of Energy Storage, 52:105016, 2022 is. The open-circuit voltage is approximated by weighted average values of two different voltage estimates. The first voltage estimate results from the low-pass-filtered difference of the terminal voltage and the excess voltage and the second estimate results from the open-circuit voltage which is calculated by current integration.

According to a further advantageous embodiment of the method according to the invention, the gain factor is determined depending on the following four terms:
a basic gain term;
a battery current sign term;
a power term of the absolute value of the cell current; and
an exponential decay term.

The gain factor may be greater than, less than or the same as 1, and adopt positive or negative values.

With the aid of the battery current sign term, it can be taken into account whether the cell is currently being charged or discharged.

The power term of the absolute value of the cell current controls the order of magnitude of the cell excess voltage with the lowest residual fault. Higher values induce an improved match in the case of high excess voltages and more fault tolerance in the case of low excess voltages and vice versa.

The exponential decay term enables the model parameters to be learnt more quickly after a parameter reset. A decay constant can be used which accelerates the learning of reset parameters. The term can also contain a factor which allows slower learning immediately after a control device wakes up, until the voltage on the RC elements of the model has been learnt through dynamic charging and discharging.

With a battery cell monitoring device, comprising detecting means for detecting the current which can be output from at least one cell of a secondary battery, the terminal voltage and a battery temperature of cells, and with a data memory and a computing unit, according to the invention the detecting means, the data memory and the computing unit are set up to run the method steps of a method described above which are carried out during the actual use of the cell. The battery cell monitoring device can be or form a part of a battery management system. As detecting means, the battery cell monitoring device can comprise or be connected to current sensors, voltage sensors and temperature sensors. The data memory may be a non-volatile memory, supplemented if necessary by a volatile memory. The computing unit may be a computer, a system on a chip (SoC) or similar. The data memory can be integrated into the computing unit.

A method described above is used according to the invention for determining the service life of battery cells of a traction battery of a vehicle with one at least partially electrified drive train, wherein the method steps carried out during the actual use of the cell are carried out in the vehicle. As explained above, with the aid of the method according to the invention, the ageing state of battery cells of a traction battery of the vehicle can be estimated in a particularly accurate and thus reliable manner. This is equivalent to the impedance of the respective cells. The cell may be a lithium-ion cell, for example. However, the method according to the invention can also be used for battery cells of a different type, such as sodium-ion cells, for example.

With a vehicle with one at least partially electrified drive train, comprising a traction battery and a battery cell ageing determination device, according to the invention the battery cell ageing determination device has a battery cell monitoring device, as described above. The battery cell ageing determination device may be a computing unit superordinate to the battery cell monitoring device. The battery cell monitoring device can also be an integral component of the battery cell ageing determination device. For example, the battery cell ageing determination device may be a battery management system, into which the battery cell monitoring device is integrated.

Further advantageous embodiments of the method according to the invention for the model-based estimation of the impedance of a galvanic cell of a secondary battery result from the exemplary embodiments which are described in more detail below with reference to the figures.

### BRIEF DESCRIPTION OF THE DRAWINGS

FIG. 1 shows a schematic representation of a battery cell monitoring device according to the invention;

FIG. 2 shows a schematic representation of an equivalent circuit diagram of a cell implemented in a cell model of an estimation model run on the battery cell monitoring device (shown in FIG. 1) and the associated impedance spectra;

FIG. 3 shows a diagram, showing the progression of a model parameter of a component contained in the equivalent circuit diagram over the impedance of the cell;

FIG. 4 shows a set of equations of the equations stored in the estimation model; and

FIG. 5 shows a flow chart of a method according to the invention for estimating the impedance of galvanic cell of a secondary battery.

### DETAILED DESCRIPTION OF THE DRAWINGS

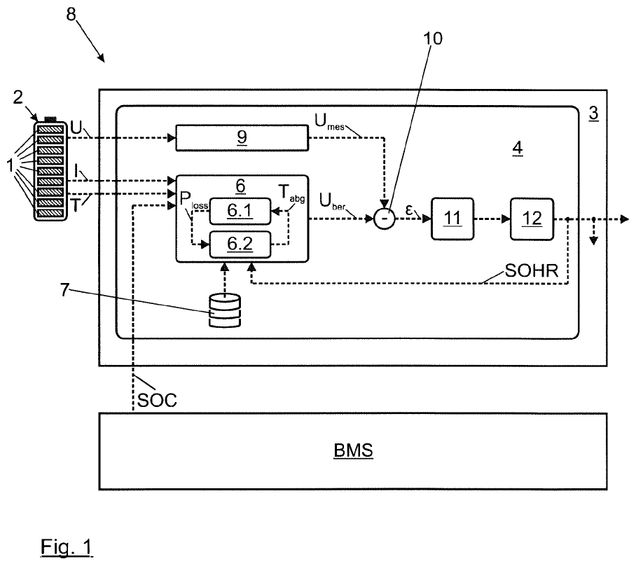

A battery cell monitoring device 8 (shown in FIG. 1) comprises a computing unit 3 which runs an estimation model 4. With the aid of the battery cell monitoring device 8, the cells 1 of a secondary battery 2 are monitored, in order to estimate their ageing-dependent impedance over the service life of the secondary battery 2. With the aid of the estimated impedance, a conclusion can be made about the ageing of the secondary battery 2.

An individual battery cell monitoring device 8 can be provided for each cell 1 of the secondary battery 2, or multiple cells 1 can be monitored with one and the same battery cell monitoring device 8. The input variables for the estimation model 4 are the current I flowing through a respective cell 1, the terminal voltage U, also known as the measured voltage Uₘₑₛ, a temperature T of the secondary battery 2, preferably of the cell 1 to be monitored, and the mathematically estimated state of charge SOC of the respective cell 1. The state of charge SOC can be provided by common methods, for example determined by a battery management system BMS. The battery management system BMS may be a part of the computing unit 3 or, as shown, may be designed separately to this.

The estimation model 4 may have a phase adaptation module 9 for adapting the phase of the measured voltage Uₘₑₛ. The cell model 6 has an electric cell model 6.1 and a thermal cell model 6.2. The electric cell model 6.1 outputs a resistance of the considered cell 1 as an output variable, or a power loss Pₗₒₛₛ and the thermal cell model 6.2, outputs the temperature T_{abg} of the respective cell 1. Furthermore, the estimation model 4 has a reference database 7 in which the development over the service life of model parameters comprised in the electric cell model 6.1 of an equivalent circuit diagram are contained.

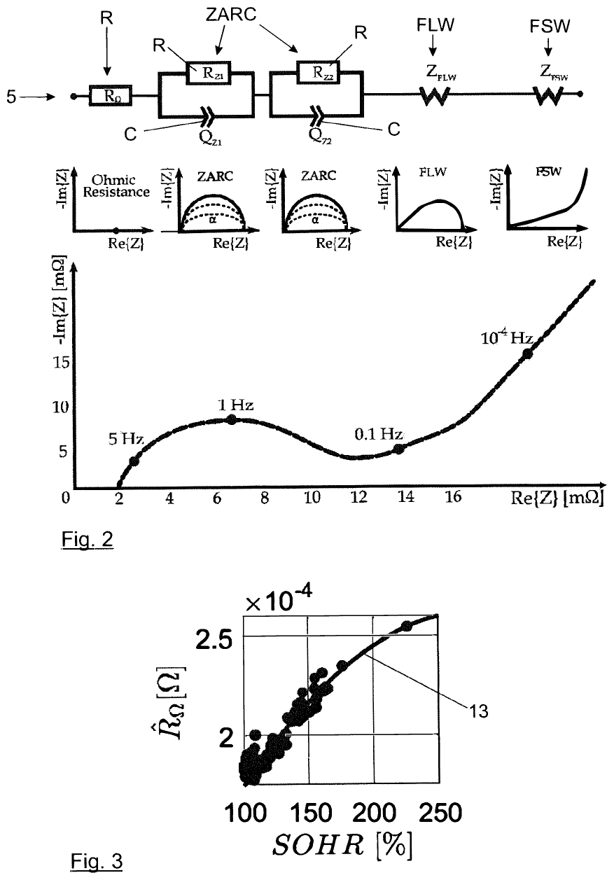

With the aid of the cell model 6, a calculated voltage U_{ber} is calculated. The measured voltage Uₘₑₛ and the calculated voltage U_{ber} are combined in a subtractor 10 and are subtracted from each other, in order to determine a difference from these variables. The difference, referred to here as fault ε, must be minimized. Thus, the fault ε is 0, if the model parameters of the equivalent circuit diagram 5 (shown in FIG. 2) or of the electric cell model 6.1, which depend on the service life of the cell 1, correspond to the real physical values. Optionally, the fault ε can be guided through a filter module 11 for smoothing, for example by means of a low-pass. Subsequently, it is fed into a control system 12, for example a PID controller. As a result, the control system 12 provides the sought ageing state of the cell 1 in the form of the estimated internal resistance, i.e., the impedance. The impedance is also referred to as a state of health resistance SOHR. The impedance is passed back into the estimation model 4 and is used as an input variable for the cell model 6. Similarly, the impedance can be taken from the estimation model 4 and even from the computing unit 3, in order to be available as an input variable for further computing models, for example as an input variable for a vehicle assistant system.

The design (shown here) of the estimation model 4 provides an iterative, i.e., incremental calculation of the impedance. The current increment of the impedance that is passed back thus serves to calculate the next increment.

FIG. 2 shows the design of the electric equivalent circuit diagram 5 of a respective cell 1. This comprises a resistance element R and two consecutive ZARC elements, ZARC, followed by two consecutive Warburg elements. In this case these are a finite space Warburg element FSW and a finite length Warburg element FLW. A ZARC element in turn comprises a capacitance element C switched in parallel to a resistance element R.

Furthermore, in FIG. 2, the impedance spectra of the respective elements and the impedance spectrum of the complete model are shown under the equivalent circuit diagram 5. Therefore, the real part of the impedance is plotted in ohms on the abscissa and the imaginary part on the ordinate.

For a fast and computationally efficient execution of the estimation model 4 in the vehicle, a correlation is required that describes which characteristics a respective model parameter of the equivalent circuit diagram 5 assumes depending on the ageing state of the cell 1, i.e., the impedance or the state of health resistance SOHR. These correlations are saved in the reference database 7 shown in FIG. 1.

FIG. 3 illustrates the process for obtaining the information stored in the reference database 7 using a diagram. The provided computational model is used in a test environment for analysing a real battery. The real battery contains differently aged cells 1. The computational model is preconfigured, based on an EIS measurement of a brand new cell. The next step is to determine the curve of the model parameters over the impedance. The curve for the individual resistance R is shown by way of example in FIG. 3. For this purpose, real, simulated or emulated discharging and charging profiles are impressed on an aged secondary battery 2, for example in a laboratory, on a test bench, or in a test vehicle. An optimization algorithm serves to determine the curve of the individual model parameters over the impedance or over the state of health resistance SOHR. The optimization algorithm has the task of minimizing the fault ε in the estimation model 4. In the process, the respective characteristics of the model parameters are altered. Thus, for each sought cell 1, corresponding model parameters are obtained for each measuring point in the characteristic diagram of the respective discharging and charging profiles for the individual cells 1 of the battery (black circles in the diagram).

However, as values for all impedance values are required in real operation, i.e., a continuous curve and not just at the points where there are black circles in the diagram, fitting is carried out to obtain the equalization curve 13. The fitting coefficients determined for determining the equalization curve 13 are then stored in the reference database 7. Thus, it is possible to determine suitable model parameter values for all of the characteristics of the impedance, i.e., state of health resistance SOHR. Then optimization does not need to be carried out again on the computing unit 3, i.e., in the respective vehicle in subsequent operation, which saves a considerable amount of computing time and thus enables the method according to the invention to be carried out particularly quickly and thus the impedance to be calculated.

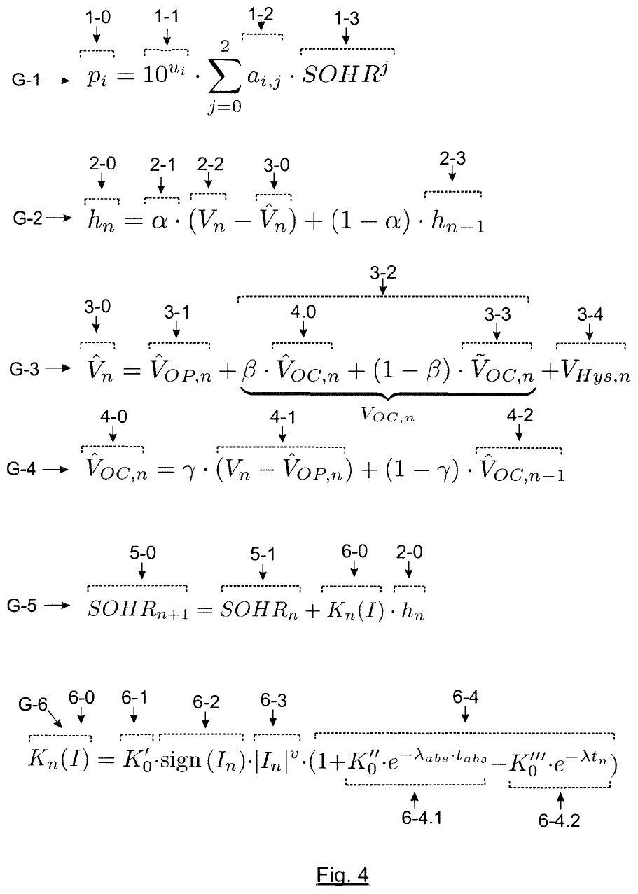

FIG. 4 shows a set of equations, that can be stored in the computational model.

Equation one G-1 describes the formula for defining different model parameters. The term 1-0 represents a respective model parameter. The term 1-1 describes the respective magnitude of the model parameter and serves to scale all of the model parameters to the same magnitude. The term 1-2 describes a coefficient. The term 1-3 represents the actual impedance. The impedance has the power j. Ideally j=2. This represents a compromise between a sufficiently quick calculation and a sufficiently accurate result. It is then a quadratic polynomial.

Equation two G-2 describes the voltage difference in the subtractor 10. The term 2-0 describes the voltage difference between the measured and the calculated voltage Uₘₑₛ and U_{ber}. The index “n” references the actual increment, or iteration. Thus, it is iterated multiple times during a sampling or calculating step. The term 2-1 describes a filter constant which may assume a value between 0 and 1, wherein alpha must be a lot less than 1. The term 2-2 corresponds to the measured voltage Uₘₑₛ for the actual increment and the term 3-0 corresponds to the calculated voltage U_{ber} for the actual increment. The term 2-4 corresponds to the voltage difference compared to the previous increment “n−1”.

Equation three G-3 describes a calculated voltage U_{ber}. The term 3-1 corresponds to the excess voltage. The term 3-2 corresponds to the open-circuit voltage. The term 3-4 corresponds to the hysteresis voltage. The term 4-0 corresponds to the low-pass-filtered difference of the terminal and excess voltage and the term 3-3 corresponds to the open-circuit voltage calculated by current integration. The variable beta is a weighting and filter constant which may assume a characteristic between 0 and 1.

Equation four G-4 describes the calculation of the term 4-0. The term 4-1 describes the difference between measured voltage Uₘₑₛ and excess voltage. The term 4-2 describes the term 4-0 in relation to the previous increment.

Equation five G-5 describes the impedance, i.e., the state of health resistance SOHR in the next increment “n+1”. The term 5-0 corresponds to the impedance of the cell 1. This shall be composed of the term 5-1, i.e., the impedance for the current increment “n” plus the product of the two terms 6-0 and 2-0, where the term 6-0 corresponds to a gain factor and the term 2-0 is the aforementioned voltage difference.

Equation six G-6 specifies the calculation rule for determining the gain factor. The term 6-1 refers to a basic gain for the return of the voltage difference. The term 6-2 describes the sign of the battery current. The term 6-3 describes a power term of the absolute value of the cell current and controls the order of magnitude of the cell excess voltage with the lowest residual fault. The variable v can assume a characteristic between 0 and 1. Higher v-values induce an improved match in the case of high excess voltages and more fault tolerance in the case of low excess voltages and vice versa. The term 6-4 describes an exponential decay term. The term 6-4.1 allows the parameters to be learnt at a rate that is K₀″ times faster at time t_{abs} after a parameter reset. The decaying constant λ thus determines the temporal decay rate of this additional gain, in order to accelerate the learning of reset parameters. The term 6-4.2 allows the parameters to be learnt at a rate that is K₀″′ times slower immediately after the computing unit 3 wakes up, until the voltage on the RC elements of the model has been learnt through dynamic charging and discharging.

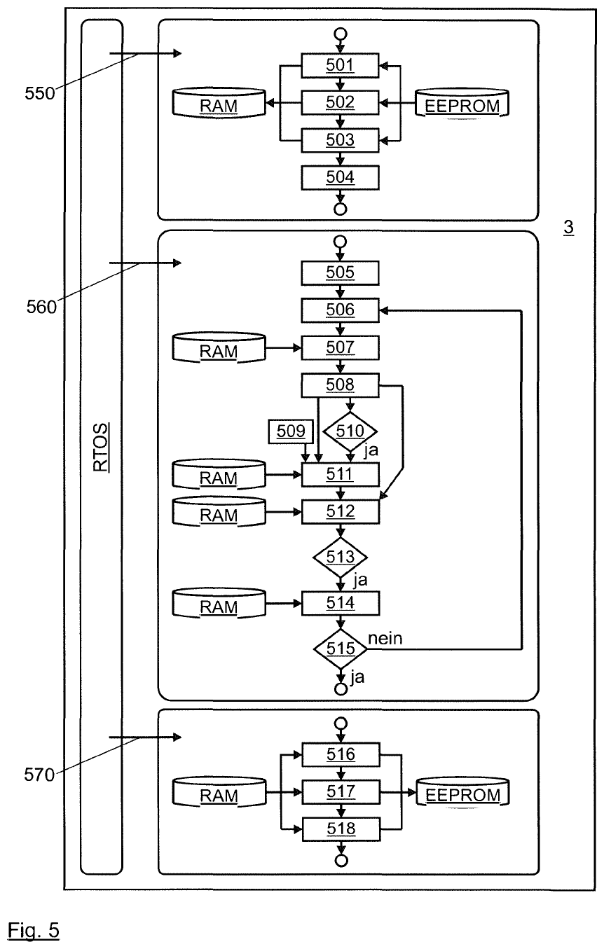

FIG. 5 shows an implementation of the estimation model 4 on an embedded system in the form of a flow chart for performing the method steps of the method according to the invention, running in a vehicle. The embedded system is formed by the computing unit 3 which represents a time-discrete control device. Preferably this is a fix point implementation which has increased performance with reduced storage use in comparison to a floating-point implementation on embedded systems. In FIG. 5, the computing unit 3 can preferably be the battery management system of the vehicle. The tick rate of the battery management system is set at a frequency of 50 Hertz, for example.

A real-time operating system RTOS of the computing unit 3 runs an initialization call 550, initiated by an initialization event, whereupon the cell model 6 is initialized. As a result, stored values for the model parameters and corresponding voltages are retrieved from a non-volatile memory EEPROM during the last runtime, i.e., before shutting down the computing unit 3, which are then written into a volatile memory RAM. In the method step 501, the ageing-dependant model parameter curves are retrieved from the reference database 7. In the method step 502, the voltage values processed last are retrieved. In the method step 503, voltages distributions for the RC elements of the cell model 6 are retrieved. In the method step 504, the RC voltages are recalculated before the computing unit 4 goes into sleep mode.

Subsequently, in the method step 560, the computing unit 3 or the real-time operating system RTOS performs a cycle call of the executable main function of the estimation model 4. In the method step 505, the measured cell voltage, the current and the estimated cell temperature are detected. If necessary, a phase adaptation of the measured voltage values is carried out, in order to synchronize the current and voltage signals. The following method steps 506 to 515 can be carried out in series for multiple, preferably all of the cells 1 of the secondary battery 2. For this purpose, the method steps 506 to 515 can be implemented as a FOR loop, for example, wherein the individual cells 1 are iterated. Thus, a cell iterator is counted in the method step 506.

In the method step 507, the ageing-dependant model parameters for the current impedance are calculated, whereby the values written in the volatile memory RAM are processed from the reference database 7.

The correlation to the already explained Arrhenius equations and temperature is taken into account here. This occurs in the method step 508 together with a calculation step for taking into account of the state of charge SOC. In the method step 509, the sleep time of the computing unit 3 is retrieved and transmitted to the model. This is necessary after a restart, in order to determine the voltage values of the RC elements in the method step 511. For this, the corresponding voltage values are required before the computing unit 3 goes into sleep mode, which are retrieved from the volatile memory RAM. It is checked in process step 510 if at this point this is the initialization after the computing unit 3 has woken up.

In the method step 512, a forward-facing calculation is carried out, in order to calculate the terminal voltage, the cell voltage and thermal losses as an output signal. The ageing factor taken into account, i.e., the impedance, is tracked by the return of the voltage values. The adjusted ageing factor, i.e., the calculated impedance for the next increment is returned in order to adapt the model parameter calculation. In the method step 513, it is checked if the current is above a minimum current value and the change in the current is thus above a corresponding limit value for the change in current. If this is the case, in the method step 514, the impedance is adjusted and written into the volatile memory RAM. In the method step 515, it is checked if this is the last cell 1 to be monitored.

In the method step 570, the real-time operating system RTOS initiates a shut-down sequence. To this end, in the method step 516, the voltages of the Warburg elements and the current model parameters (i.e., the model parameters adapted to the ageing) are written into the volatile memory EEPROM for each cell 1. In the method step 517, the voltage distributions of individual Warburg elements for RC voltages are analogously written to the non-volatile memory EEPROM. however only for a single cell 1. In the method step 518. the impedances of the individual cells 1. i.e., the ageing factors, are stored. Thus, the method ends.

1.-8. (canceled)

9. A method for a model-based estimation of an impedance of a galvanic cell (1) of a secondary battery (2) by an estimation model (4) run on a computing unit (3), wherein at least some model parameters of an equivalent circuit diagram (5) of the galvanic cell (1) in a cell model (6) contained in the estimation model (4) are adapted over a service life of the galvanic cell (1) and wherein the equivalent circuit diagram (5) comprises at least one resistance element (R) and one capacitance element (C), the method comprising the steps of:
carrying out the following method steps prior to an actual use of the galvanic cell (1):
initially parameterizing the cell model (6) based on measurement series of electrochemical impedance spectroscopy of a structurally identical cell (1);
generating a reference database (7) comprising an allocation of model parameter reference values and corresponding impedance reference values over a service life characteristic diagram of the structurally identical cell (1) by:
impressing a plurality of temperature-specific charging and discharging profiles, each comprising a voltage curve of the cell (1) over time on the estimation model (4);
thereby adjusting the model parameters to be adapted of the equivalent circuit diagram (5) by a non-linear optimizer, wherein a difference between measured cell voltage (Uₘₑₛ) and cell voltage (U_{rec}) calculated by the cell model (6) is formed and minimized, wherein model parameters found in respective minima are used to form the model parameter reference values; and
calculating the impedance reference values corresponding to the model parameter reference values;
fitting a respective model parameter reference value from the reference database (7) by polynomial fitting and saving the fitting coefficients determined in the process in a data memory;
and by carrying out the following method steps during the actual use of the galvanic cell (1):
determining a difference from a measured cell voltage (Uₘₑₛ) and a cell voltage (U_{rec}) calculated by the cell model (6);
specifying a gain factor and multiplying the voltage difference, determined in the previous method step, by the gain factor; and
incrementally determining the impedance of the galvanic cell (1), wherein a next increment of the impedance is calculated by adding a current increment of the impedance to a product calculated in the previous method step of gain factor and voltage difference, wherein subsequently the variable model parameters are adjusted to the next increment of the impedance thus calculated, taking the fitting coefficients into account.

10. The method according to claim 9, wherein the equivalent circuit diagram (5) of the galvanic cell (1) additionally contains at least one of the following further elements:
a ZARC element (ZARC);
a coil element;
a finite length Warburg element (FLW); and/or
a finite space Warburg element (FSW).

11. The method according to claim 9, wherein the voltage difference of the measured cell voltage (Uₘₑₛ) and the calculated cell voltage (U_{rec}) is low-pass-filtered prior to multiplication by the gain factor.

12. The method according to claim 9, wherein the cell model (6) for calculating the cell voltage (U_{rec}) takes into account a term for an excess voltage (3-1), a hysteresis voltage (3-4), and an open-circuit voltage (3-2).

13. The method according to claim 9, wherein the gain factor is determined depending on the following four terms:
a basic gain term (6-1);
a battery current sign term (6-2);
a power term of the absolute value of the cell current (6-3); and
an exponential decay term (6-4).

14. The method according to claim 9, wherein the method is used to determine a service life of battery cells of a traction battery of a vehicle with one at least partially electrified drive train, wherein the method steps carried out during the actual use of the galvanic cell (1) are carried out in the vehicle.

15. A battery cell monitoring device (8), comprising:
a detector for detecting a current output from at least one cell (1) of a secondary battery (2), a terminal voltage, and a battery temperature;
a data memory; and
a computing unit (3),
wherein the detector, the data memory, and the computing unit (3) are configured to run the method according to claim 9 which are carried out during the actual use of the galvanic cell (1).

16. A vehicle with one at least partially electrified drive train, comprising:
a traction battery; and
a battery cell ageing determination device;
wherein the battery cell ageing determination device has a battery cell monitoring device (8) according to claim 15.
